(19) United States
(12) Patent Application Publication
(10) Pub. No.: US 2011/0057240 A1
(43) Pub. Date: Mar. 10, 2011

(54) SEMICONDUCTOR DEVICE AND METHOD OF MANUFACTURING THE SAME

(75) Inventor: Hyung Jin Park, Icheon (KR)

(73) Assignee: Hynix Semiconductor Inc., Icheon (KR)

(21) Appl. No.: 12/824,062

(22) Filed: Jun. 25, 2010

(30) Foreign Application Priority Data
Sep. 8, 2009 (KR) 10-2009-0084535

(51) Int. Cl. H01L 27/108; H01L 29/92; H01L 21/02

(52) U.S. Cl. 257/303; 257/532; 438/387; 257/E21.008; 257/E29.342; 257/E27.084

(57) ABSTRACT

A semiconductor device includes a plurality of conduction plugs disposed on an active region, a bit line connected to a conduction plug of the plurality of conduction plugs which is disposed in a central portion of the active region, and storage nodes connected with conduction plugs of the plurality of conduction plugs which are disposed at both peripherals of the active region and passing over the active region.

### CROSS-REFERENCES TO RELATED APPLICATION

This application claims priority under 35 U.S.C. 119(a) to Korean application number 10-2009-0084535, filed on Sep. 8, 2009, in the Korean Patent Office, which is incorporated by reference in its entirety as if set forth in full.

### BACKGROUND OF THE INVENTION

The present invention relates to a semiconductor device and, more particularly, to a semiconductor device including a storage node penetrating a bit line and a method of manufacturing the same.

The semiconductor devices need to be more highly integrated in order to satisfy the consumers demand for high performance and low price. As the integration degree of the semiconductor devices is increased, design rules are scaled down and patterns of the semiconductor device are miniaturized. As the semiconductor device becomes miniaturized and highly integrated, the total dimension of the chip does not increase in proportion to the increment in the memory capacity, but a dimension of a cell area in which patterns of the memory device are formed is substantially reduced. Accordingly, in order to ensure the desired memory capacity, because many patterns need to be formed in the defined area, the fine patterns where the critical dimensions are scaled down need to be formed.

The reduction in the dimension of the cell capacitor is accompanied by a reduction in the dimension of the cell area and the sensing margin and sensing speed are lowered and the endurance to soft error due to particles is degraded. Accordingly, a method for ensuring a sufficient capacitance in the restricted area is needed.

On the other hand, the contacts for connecting upper and lower interconnections are largely affected by the design rule as compared with the line/space patterns. Accordingly, as the device becomes highly integrated, the size of the device and the distance between neighboring interconnections are reduced. According to this, the aspect ratio which is the ratio of the depth to the diameter of the contact is increased and becomes difficult to form contact holes. Therefore, the contact formation process is very important in manufacturing the high integration semiconductor device. Accordingly, when the contacts are formed in the high integration semiconductor device having multi-layered interconnections, because an accurate and strict alignment is required, the process margin is reduced or the process has to be performed without margins.

In particular, there are many difficulties in forming a storage node contact connected to a storage node for storing data due to the above reasons as follows.

First, the bottom of the storage node contact hole has a narrow critical dimension due to high integration. Accordingly, when the etching process is performed to the define the storage node contact, the storage node contact hole should be formed to expose the active region. However, it is difficult to perform the etching process to expose the active region due to the narrow bottom of the storage node contact hole.

Second, an electrical short between the storage node contact and the gate occurs frequently. When the etching process is carried out to define the storage node contact hole, an over etching process is carried out to solve the above problem that the bottom of the storage is not exposed so that the CD at the bottom of the storage node can be ensured. However, when an over-etching process is performed, an underlying insulating layer such as the bit line spacer may be attacked so that an electrical short between the storage node contact and the bit line can occur.

Third, the overlap margin between the storage node contact and the active region is insufficient. Although the above problems are solved, the contact area between the storage node contact and the active region is gradually reduced due to the high integration of the semiconductor device. Accordingly, the contact resistance between storage node and the active region is increased due to the reduction of the electrical contact area between them so that the performance of the semiconductor device is degraded.

### SUMMARY

The inventive concept is to solve the problems that because the storage node contact is formed by using the spacers formed on side walls of the bit line as a barrier through a self-aligned contact method, it is difficult to form the storage node due to variation of the process parameter according to the width of the bit line.

According to one aspect of an exemplary embodiment, a semiconductor device comprises first, second and third conduction plugs disposed on an active region, the second conduction plug being provided between the first and third conduction plugs, a bit line electrically coupled to the second conduction plug and passing over the active region, storage nodes electrically coupled to the first and third conduction plugs, respectively.

The storage nodes may extend through the bit line.

A bottom of the storage node may have a slit shape elongated in a longitudinal direction of the bit line.

The semiconductor device may further include an insulating layer disposed on lower portions of sidewalls of the storage nodes.

The insulating layer may be disposed on sidewalls of the bit line.

The insulating layer may comprise an oxide layer or a nitride layer.

The insulating layer may have a thickness of 50 Å to 100 Å.

An upper portion of each storage node may have a cylindrical shape and a lower portion of each storage node may have a concave shape.

The semiconductor device may further include a dielectric layer disposed on a surface of the storage nodes and an upper electrode disposed on a surface of the dielectric layer.

The dielectric layer may comprise a stack structure of ZrO₂, Al₂O₃, and ZrO₂.

According to another aspect of another exemplary embodiment, a semiconductor device comprises an active region formed over a substrate, first, second and third conduction plugs disposed on an active region, the second conduction plug being provided between the first and third conduction plugs, a bit line electrically coupled to the second conduction plug and passing over the active region, storage nodes electrically coupled to the first and third conduction plugs, respectively, wherein the storage nodes and the bit line are formed in the same cross-sectional plane as a cross-sectional plane of the active region.

According to one aspect of an exemplary embodiment, a method of manufacturing a semiconductor device comprises: forming first, second and third conduction plugs on an active region, the second conduction plug being provided between the first and third conduction plugs, forming a bit line electrically coupled to the second conduction plug and passing over the active region, forming storage nodes electrically coupled to the first and third conduction plug respectively, wherein the bit line and storage nodes are formed in the same cross-sectional plane as a cross-sectional plane of the active region.

According to another aspect of another exemplary embodiment, a method of manufacturing a semiconductor device comprises: forming first, second and third conduction plugs on an active region, the second conduction plug being provided between the first and third conduction plugs, forming a bit line electrically coupled to the second conduction plug and passing over the active region, forming storage nodes electrically coupled to the first and third conduction plug respectively, the first conduction plug contacting one end of the active region and third conduction plug contacting an opposing end of the active region.

The method may further comprises forming recess gates, before the forming a plurality of conduction plugs.

The forming a bit line may comprises forming a first interlayer insulating layer on the first, second and third of conduction plugs, forming a first photosensitive pattern on the first insulating layer exposing the second conduction plug, etching the first interlayer insulating layer by using the first photosensitive pattern as an etch mask, forming a bit line conduction layer to be buried within an etched portion of the interlayer insulating layer, forming a second photosensitive pattern on the bit line conduction layer to cover the active region, and etching the bit line conduction layer by using the second photosensitive pattern as an etch mask.

The method further comprises forming bit line spacers on sidewalls of the bit line, after the forming the bit line.

The method may further comprises forming a second interlayer insulating layer, after the forming the bit line.

The forming the storage nodes may comprise forming holes exposing the first and third conduction plugs disposed on the active region, forming an insulating layer on sidewalls of the holes, forming a storage node material on exposed the first and third conduction plugs and sidewalls of the insulating layer, and removing the second interlayer insulating layer and the insulating layer to form first storage nodes.

The forming holes may comprise etching the second interlayer insulating layer, the bit line and the first interlayer insulating layer.

The forming an insulating layer may include forming an insulating material on the holes and etching back the insulating material.

After the forming a first storage node, the method may further include forming an etching stop layer and third and fourth interlayer insulating layers on the first storage nodes, forming upper holes by etching the third and fourth interlayer insulating layers to expose the etching stop layer, forming a storage node material on the upper holes, etching back the storage node material, and forming second storages node by removing the third and fourth interlayer insulating layers to expose the etching stop layer and by removing the etching stop layer to expose the first and third conduction plugs.

The forming the second storage nodes may comprise carrying out a full dip out process using HF.

The method may further include forming a dielectric layer on a surface of the storage nodes and forming an upper electrode on dielectric layer.

The inventive concept can solve the not-open phenomenon in the bottom of the storage node contact due to bit line pitch and the short due to the electrical connection between the storage node and the bit line and also solve the increase in the bit line resistance by increasing the width of the bit line. Furthermore, the inventive concept forms the storage node having a cylindrical shape at the upper portion and a concave shape at the lower portion to prevent the collapse of the storage node as well as to increase the capacitance.

These and other features, aspects, and embodiments are described below in the section entitled “DESCRIPTIOM OF EXEMPLARY EMBODIMENT”.

### BRIEF DESCRIPTION OF THE DRAWINGS

The above and other aspects, features and other advantages of the subject matter of the present disclosure will be more clearly understood from the following detailed description taken in conjunction with the accompanying drawings.

FIG. 1 is a diagram illustrating a semiconductor device according to an embodiment of the present invention, wherein (i) is a plan view and (ii) is a sectional view taken along the line x-x1 of (i).

FIGS. 2A to 2H are diagrams illustrating a method of manufacturing the semiconductor device of FIG. 1 according to an embodiment of the present invention, wherein (i) is a plan view and (ii) is a sectional view taken along the line x-x1 of (i).

FIGS. 3A through 3F are diagrams illustrating a method of manufacturing a semiconductor device according to another embodiment of the present invention, wherein (i) is a plan view and (ii) is a sectional view taken along the line x-x1 of (i).

FIGS. 3G through 3M are sectional views illustrating a method of manufacturing a semiconductor device according to another embodiment of the present invention.

### DESCRIPTION OF EXEMPLARY EMBODIMENT

Embodiments are described herein with reference to cross-sectional views. Many variations, for example, in manufacturing techniques and/or tolerances, are available. Thus, embodiments shown here should not be construed as limited to the particular shapes of regions illustrated herein but may include deviations in shapes that result, for example, from manufacturing. In the drawings, lengths and sizes of layers and regions may be exaggerated for the purpose of explanation. Like reference numerals in the drawings denote like elements. It is also understood that when a layer is referred to as being “on” another layer or substrate, it can be directly on the other layer or substrate, or intervening layers may also be present.

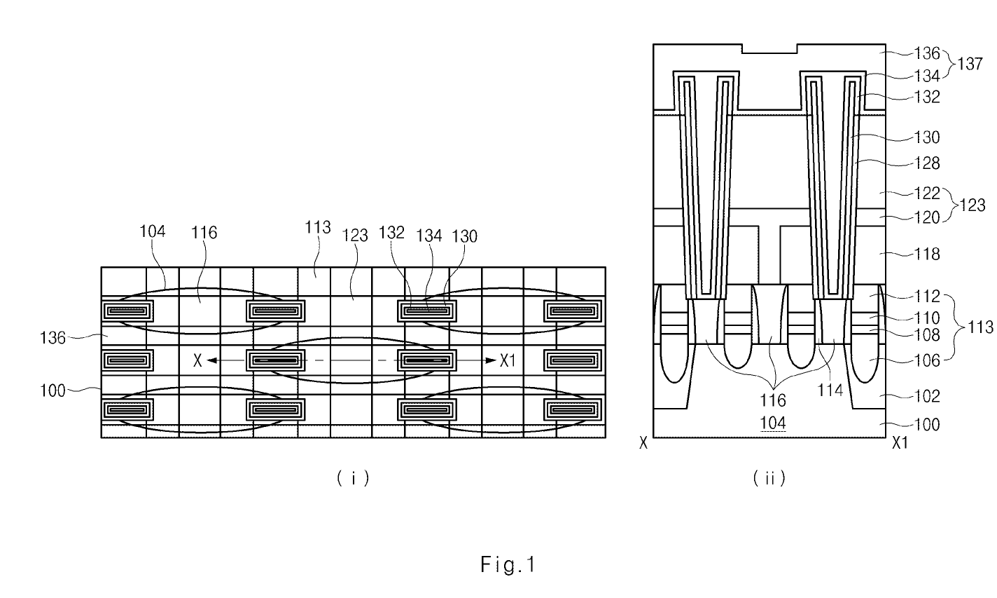

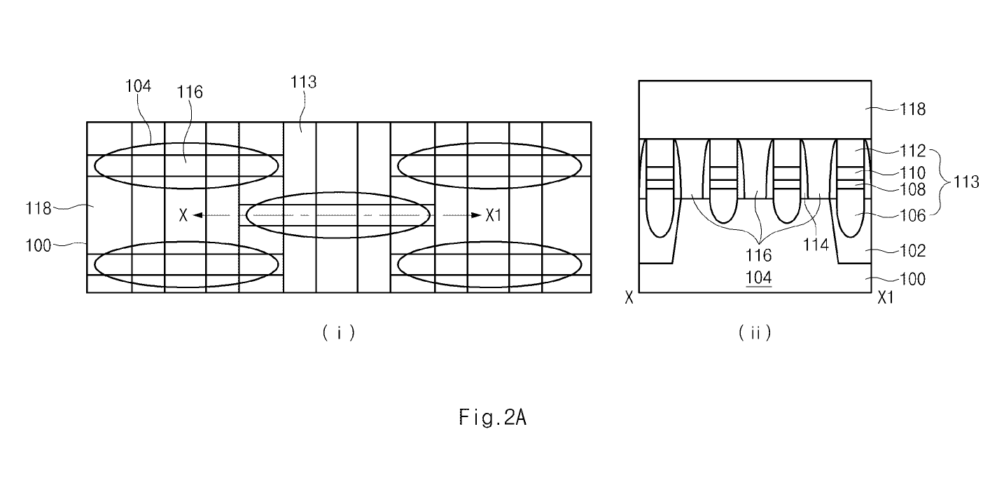

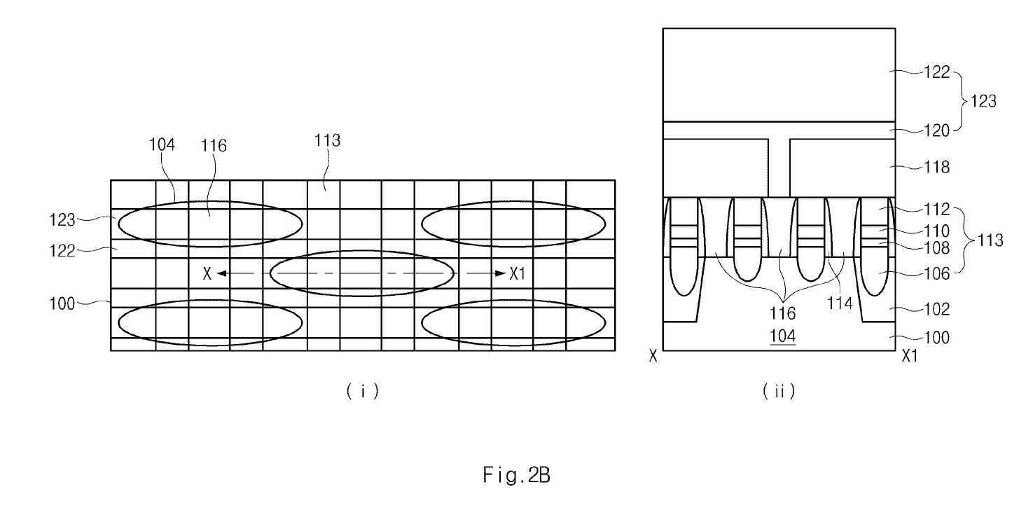

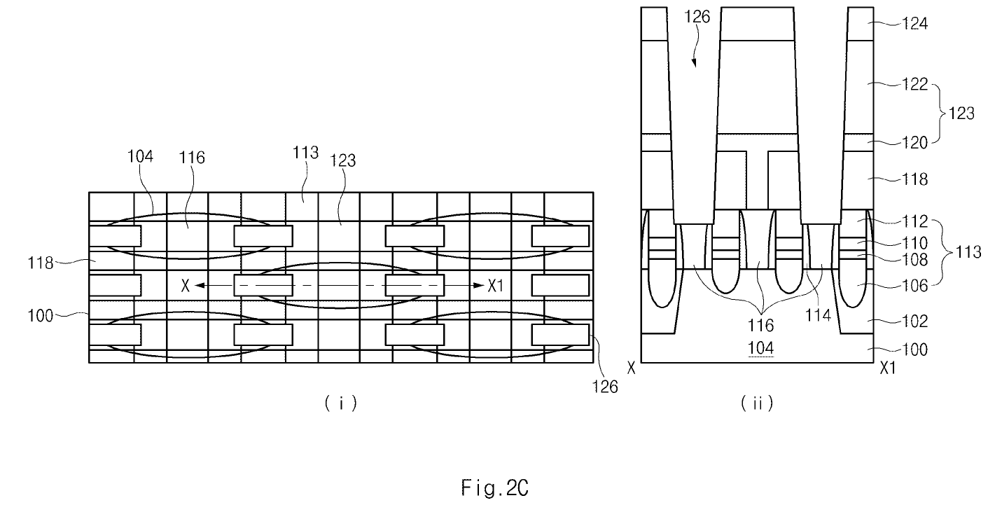

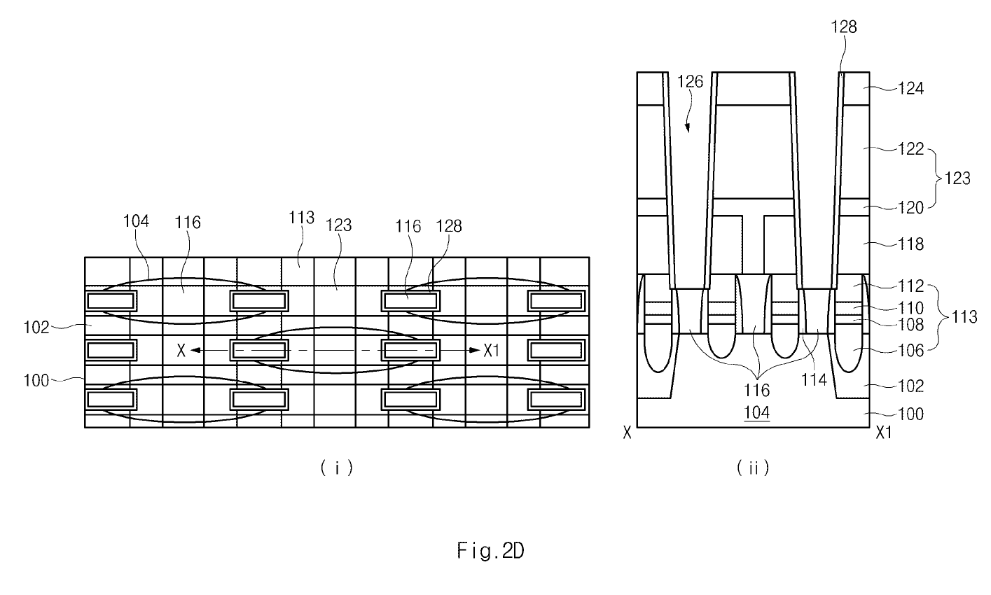

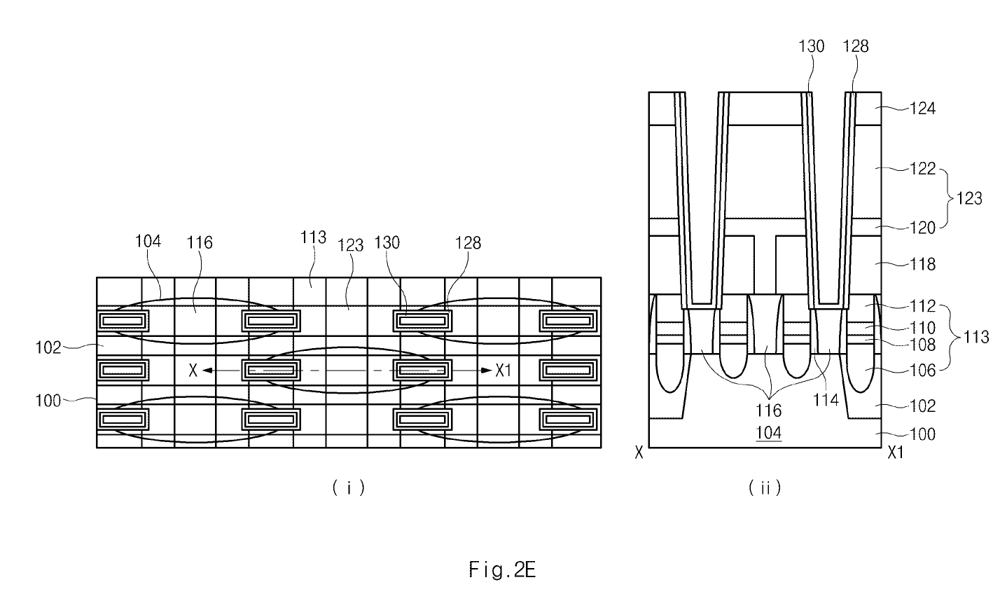

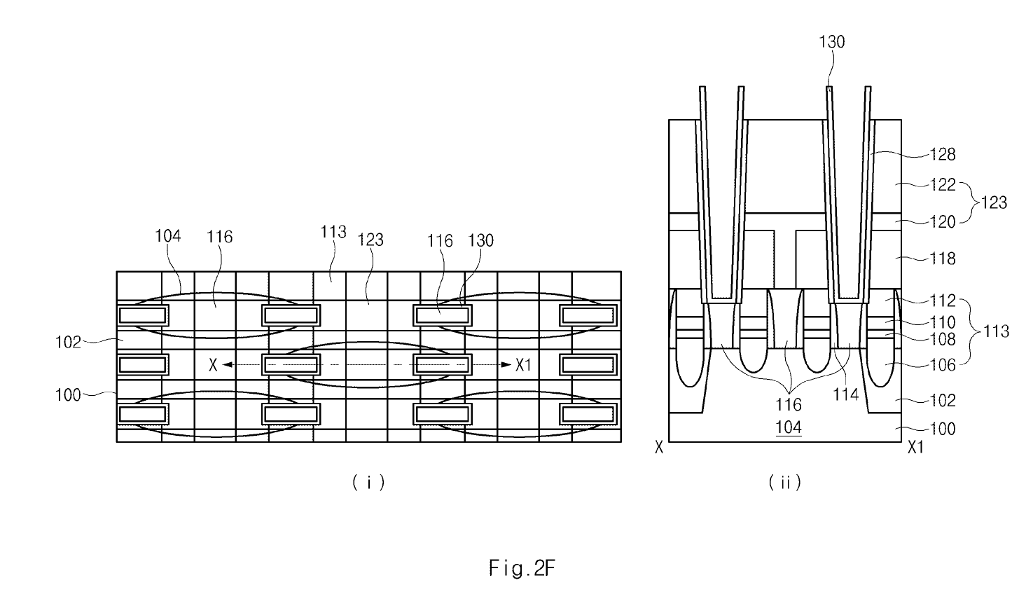

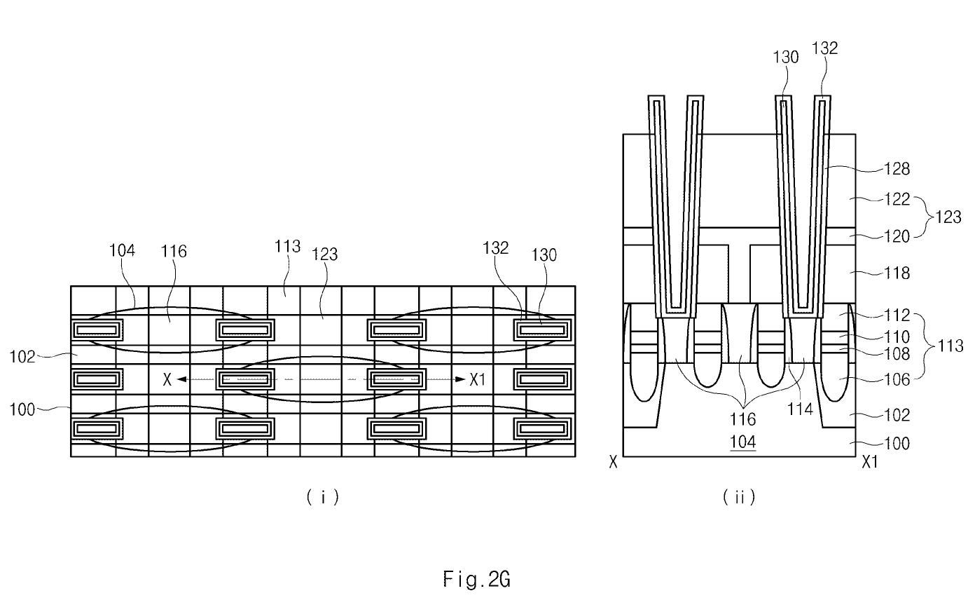

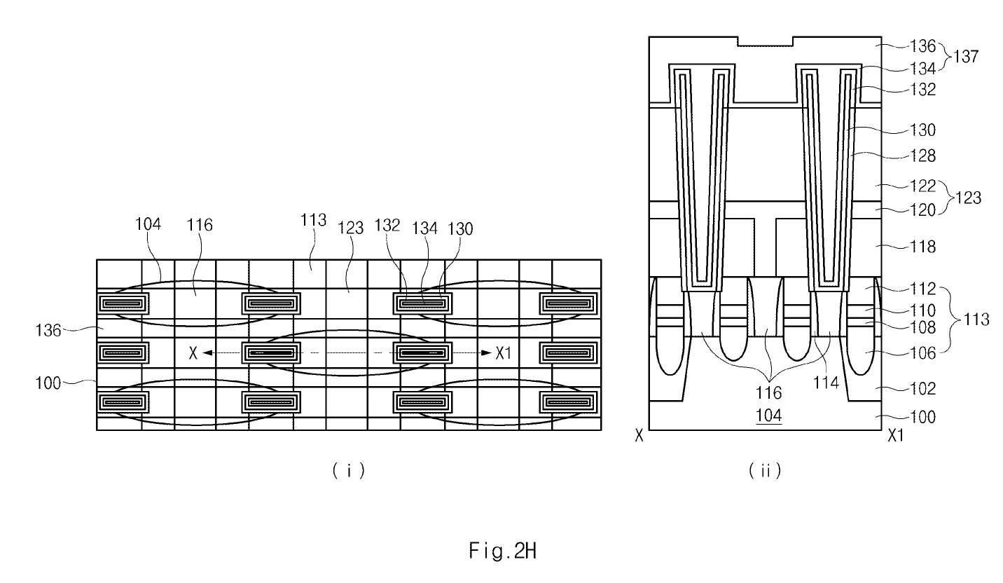

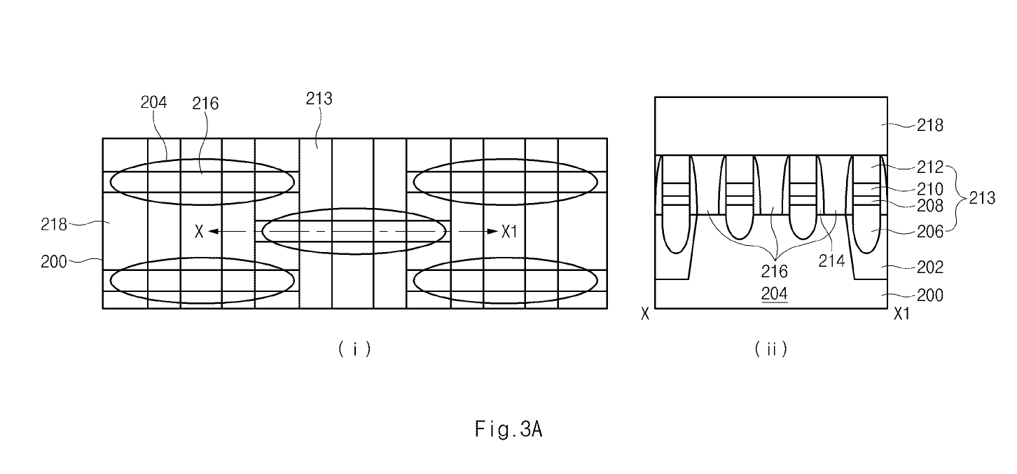

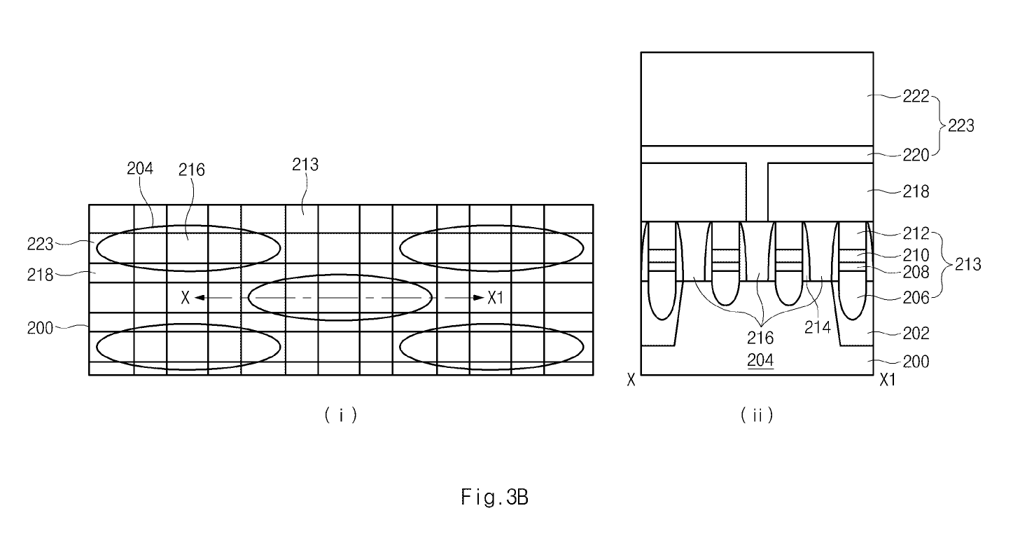

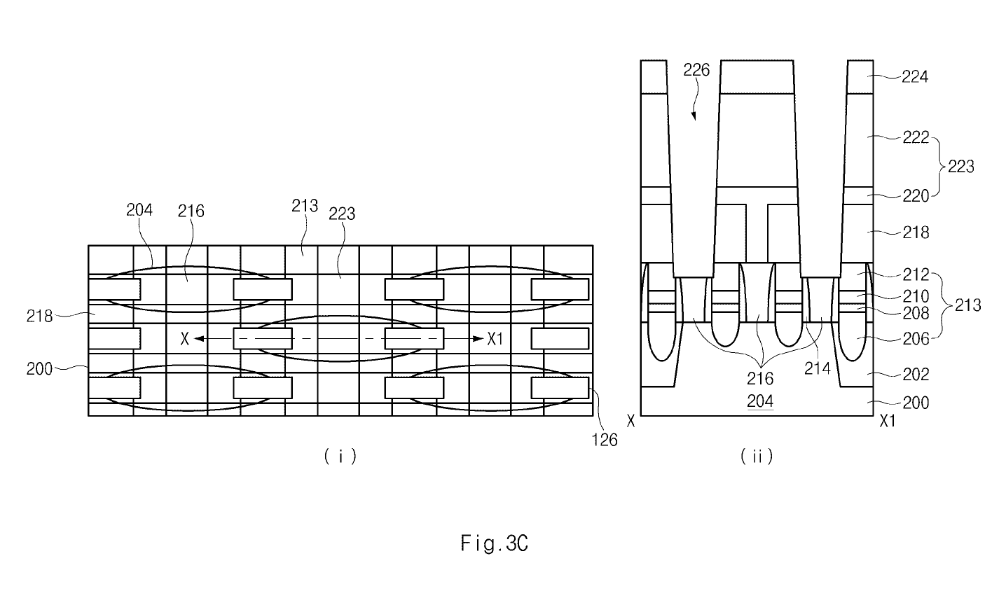

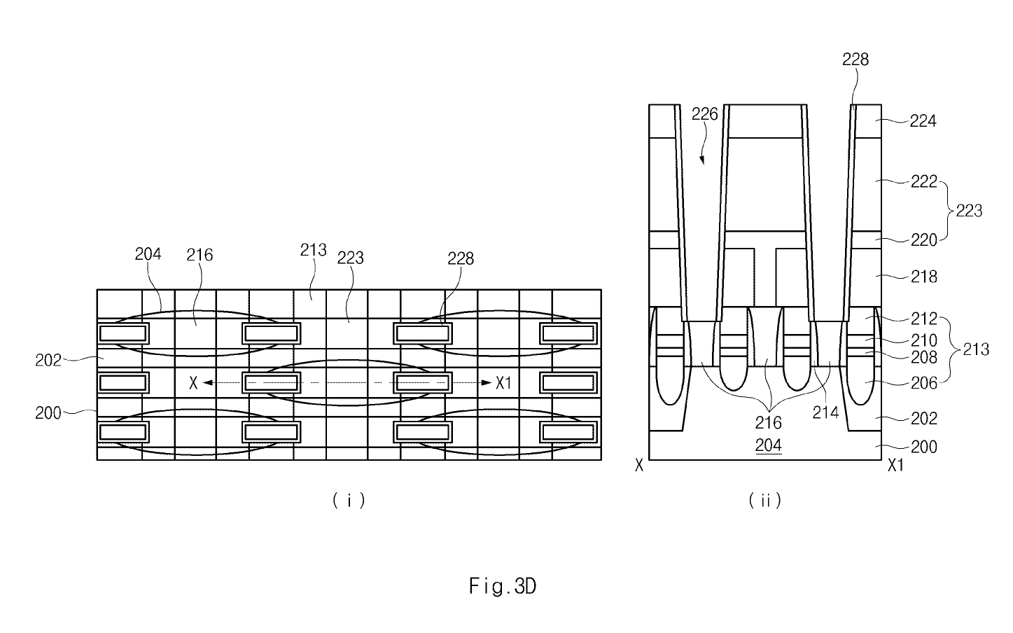

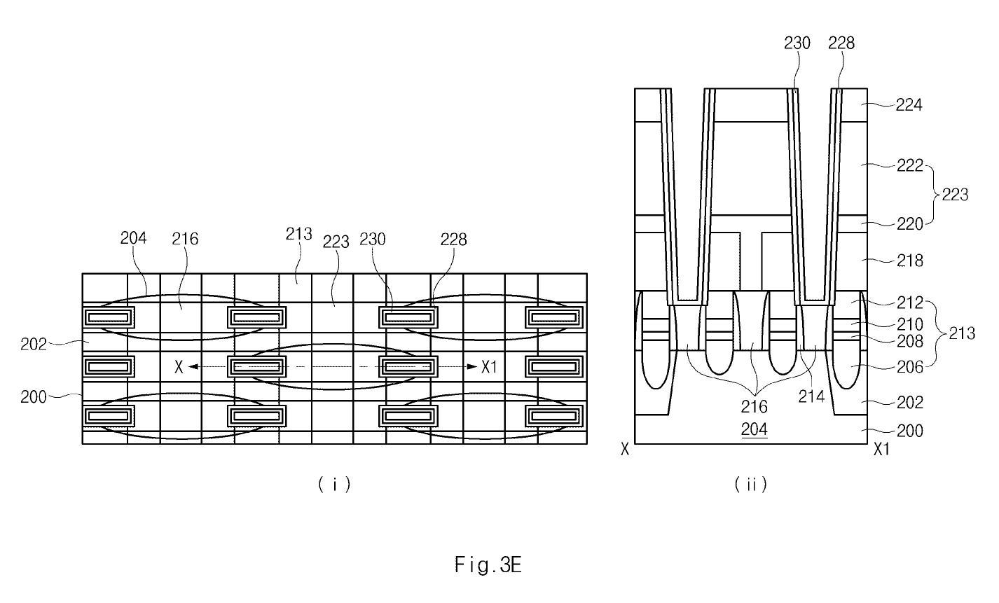

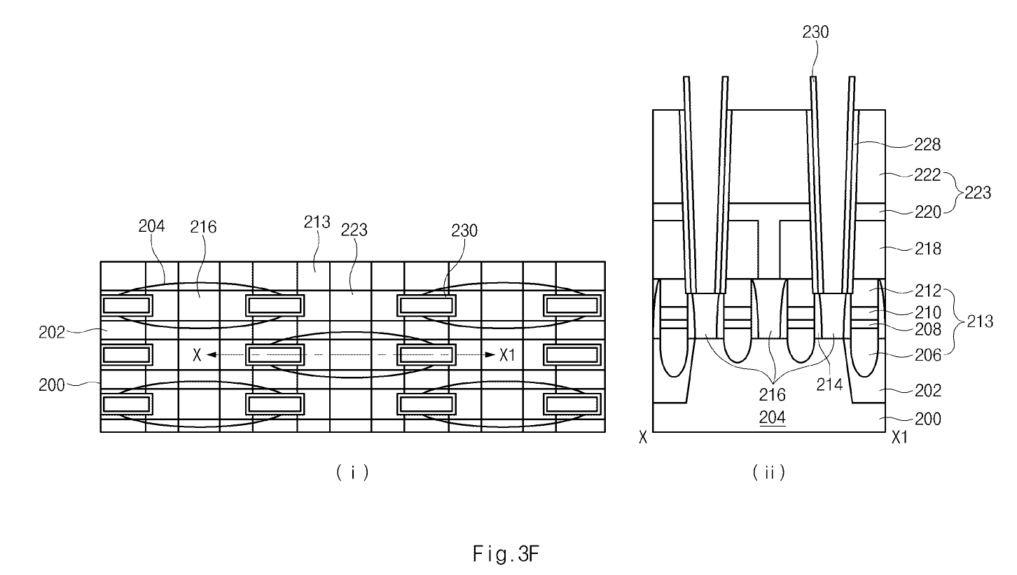

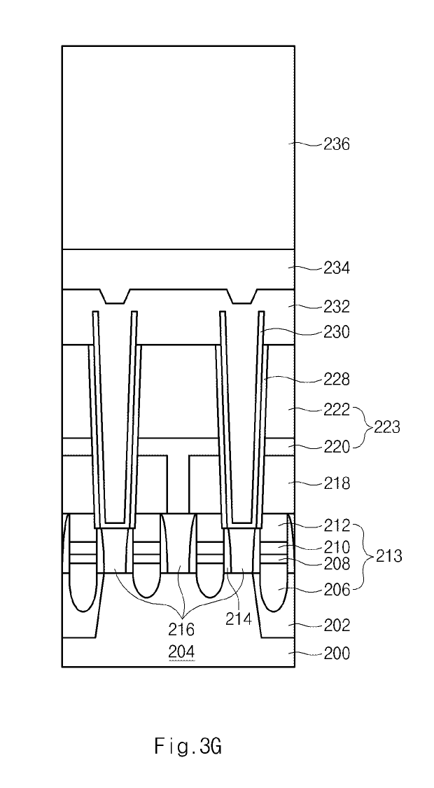

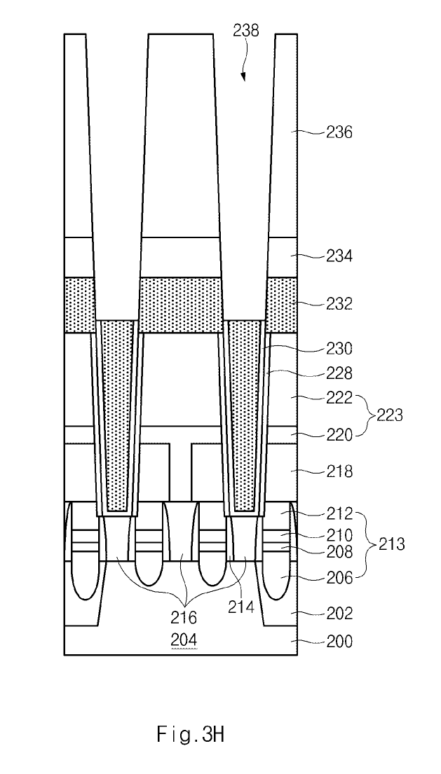

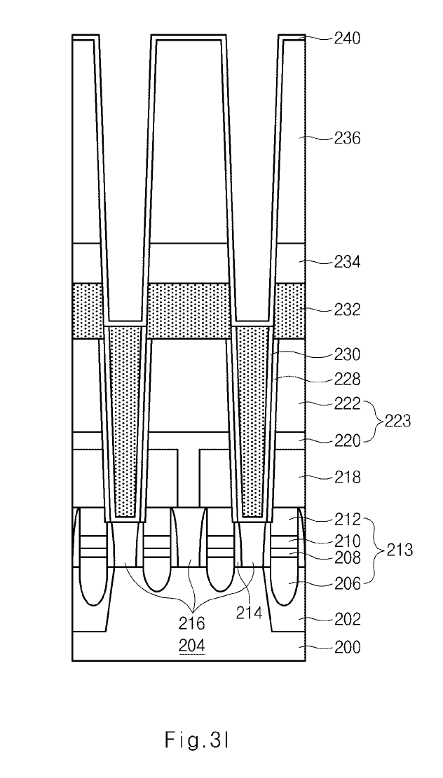

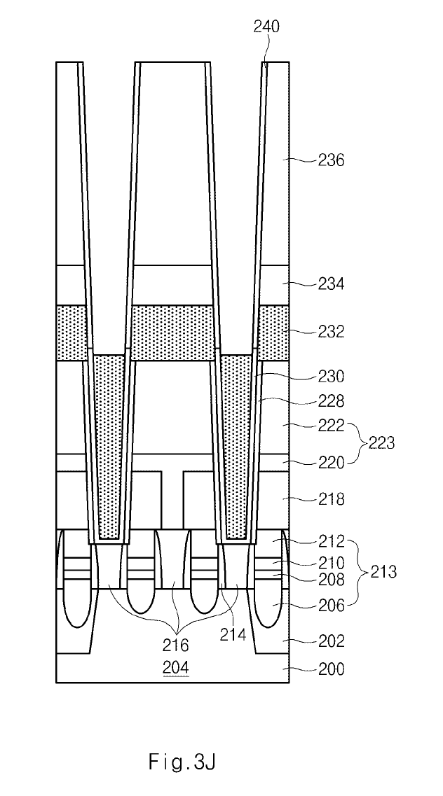

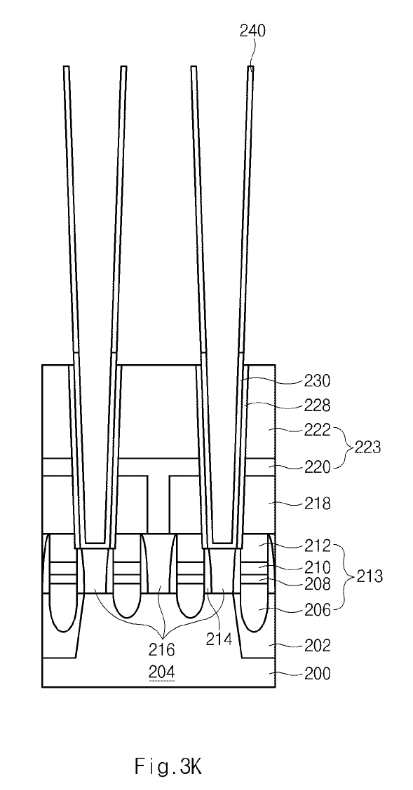

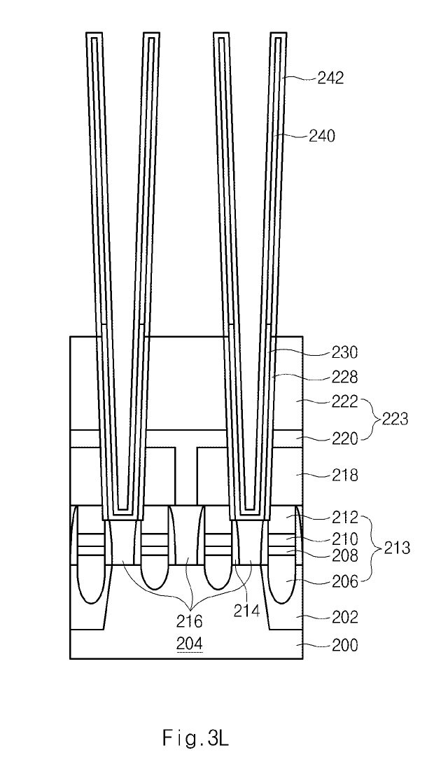

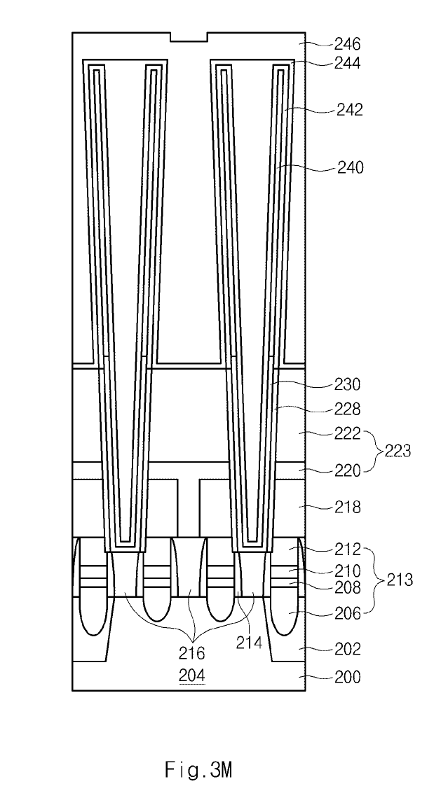

FIG. 1 is a diagram showing a semiconductor device according to an embodiment of the present invention, wherein (i) is a plan view and (ii) is a sectional view taken along the line x-x1 of (i). FIGS. 2A to 2H are diagrams illustrating a method of manufacturing the semiconductor device shown in FIG. 1, in each of which (i) is a plan view and (ii) is a sectional view taken along the line x-x1 of (i). FIGS. 3A to 3M are diagrams illustrating a method of manufacturing a semiconductor device according to another embodiment of the present invention, in each of which (i) is a plan view and (ii) is a sectional view taken along the line x-x1 of (i). Herein, FIGS. 3G to 3M show sectional views illustrating the method of manufacturing a semiconductor device according to another embodiment of the present invention.

Referring to FIG. 1, the semiconductor device includes a plurality of conduction plugs 116 disposed on an active region 104, a bit line 123 connected to the conduction plugs 116 which is disposed at a central portion of the active region 104, and a storage node 130 connected to the conduction plug 116 which are disposed at both peripherals of the active region 104. The bit line 123 passes over the active region 104.

At this time, the conduction plug 116 may serve as a landing plug. And the conduction plugs 116 is include a first, second, and third conduction plugs disposed on an active region, the second conduction plug being provided between the first and third conduction plugs. A bit line 123 electrically coupled to the second conduction plug and passing over the active region. The storage nodes 130 are preferably formed to electrically coupled the first and third conduction plugs, respectively.

The storage nodes 130 are preferably formed to penetrate the bit line 123, but is not limited thereto and is merely exemplified to embody the semiconductor device of the present embodiment. Accordingly, it is changeable to any structure where the bit line 123 is formed over the active region 104 and the storage nodes 130 are formed over the active region.

An insulating layer 118 may be preferably disposed at lower portions of the sidewalls of the storage node 130 and the insulating layer 118 is preferably formed on sidewalls of the bit line 123. Herein, the insulating layer 118 is preferably formed of an oxide layer or a nitride layer. As described above, the insulating layer 118 insulates the storage node 130 from the bit line 123, and may preferably have a thickness of 50 Å to 100 Å. The storage node is preferably in a cylindrical shape at an upper portion and in a concave shape at a lower portion. According to this configuration, it can prevent the storage node from easily collapsing and can maximize the capacitance.

The semiconductor device further includes recess gates disposed between the conduction plugs 116. The semiconductor device further includes bit line spacers (not shown) formed on sidewalls of the bit line 123. The semiconductor device further includes an upper electrode 137 disposed over the storage node with a dielectric layer 132 interposed therebetween. Herein, the dielectric layer 132 may be formed of a stack layer of ZrO₂, Al₂O₃ and ZrO₂.

The semiconductor forms the bit line 123 on the active region 104 and connects the storage node 130 to the conduction node 130 to the conduction plug 116 so that it doesn't have to separately from a bit line contact and the storage node contact. According to the present invention, both of the bit line 123 and the storage node 130 are formed over the active region 104. More specifically, unlike a conventional art, the bit line 123 and the storage node 130 are formed in a same cross-sectional plane as a cross-sectional plane of the active region 104. Accordingly, the width of the bit line doesn't depend on the storage node contact so that the margin of the bit line width can be ensured and the increase of the bit line resistance can be prevented.

Referring to FIG. 2A, recesses (not shown) of a predetermined depth are formed by etching a semiconductor substrate 100 including the active region 104 defined by an isolation layer 102. Next, a gate polysilicon layer 106, a gate metal layer 108, a hard mask layer 110 and a silicon nitride layer 112 are sequentially stacked in the recesses and a photoresist pattern (not shown) defining a gate is formed on the silicon nitride layer 112. The silicon nitride layer 112, the hard mask layer 110, the gate metal layer 108 and the gate polysilicon layer 106 are etched by using the photoresist pattern as an etch mask to form gates 113.

Next, a spacer material (not shown) is formed on an entire resultant structure including the gates 113 and then etched back to form gate spacers 114 on the sidewalls of the gates 113. An interlayer insulating layer (not shown) is formed on the entire resultant structure and etched to form contact holes (not shown) exposing portions of the active region 104 between the gates 113. A conductive material is deposited to fill the contact hole and then planarized to form the conduction plugs 116. The conduction plugs 116 include a first conduction plug formed at one side of the gate pattern 113 and a second conduction plug formed at the other side of the gate pattern 113. Next, an interlayer insulating layer 118 is formed on an entire resultant structure.

Referring to FIG. 2B, a photoresist pattern (not shown) is formed on the interlayer insulating layer 118 to expose the first conduction plug 116 and then the interlayer insulating layer 118 are etched by using the photoresist pattern as an etch mask to expose the first conduction plug 116. Next, a bit line conduction layer 120 and a hard mask layer 122 are formed on an entire resultant structure and a photoresist pattern (not shown) is formed on the hard mask layer 122 to cover the active region 104. The bit line 123 is formed in the active region 104 adjacent along the longitudinal direction (x-x1) to be overlapped with the active region 104 as shown in FIG. 2B(i). Since the bit line 123 and the storage node 130 are formed in the same cross sectional plane, a larger margin can be ensured to form either the bit line 123 or the storage node 130. Furthermore, since the bit line 123 and the storage node 130 are formed in the same cross sectional plane, no additional contact plug other than the first and the second conduction plug 116 is necessary. Thus, contact resistance can be reduced between the substrate and the bit line 123, and between the substrate and the storage nodes 130. Herein, the bit line conduction layer 120 may preferably include a tungsten layer.

Referring to FIG. 2C, an interlayer insulating layer 124 is formed on the hard mask layer 122 and a photoresist pattern (not shown) is formed on the interlayer insulating layer 124 to expose the second conduction plug 116 formed at the other side of the gate 113. The interlayer insulating layer 124, the bit line 123 and the interlayer insulating layer 118 are etched by using the photoresist pattern as an etch mask to form holes 126 exposing the second conduction plug 116. At this time, the holes 126 may be preferably formed under the consideration of the width of the bit line 123. That is, the holes 126 are preferably formed to have a width narrower than the width of the bit line 123 so that the holes 126 are formed within the bit line 123. Accordingly, a bottom of the hole 126 preferably has a slit elongated in the longitudinal direction of the bit line 123.

Referring to FIG. 2D, an insulating layer 128 is formed on the inner side walls of the holes 126. In more detail, an insulating layer is formed on an entire resultant structure and then is subject to an anisotropic etch process to form the insulating layer 128 on the inner sidewalls of the holes 126. Herein, the insulating layer 128 may be formed of a nitride layer or an oxide layer, and have a thickness of 50 Å to 100 Å. The insulating layer 128 insulates the bit line 123 from a storage node to be formed in a subsequent process.

Referring to FIG. 2E, a storage node material is formed on an entire resultant structure and then etched back to form storage nodes 130 on the insulating layer 128 and on the conduction plugs 116. Herein, the storage nodes 130 may be formed of any one of Ti, TiN and a combination thereof. Because the storage nodes 130 can be directly contacted with the second conduction plugs 116 without passing through an additional contact plug extended from the second conduction plug 116, production process can be simplified and the processing time and cost can be saved. The storage nodes 130 serve as a lower electrode of a transistor capacitor. A bottom of each storage node 130 has a slit shape elongated in a longitudinal direction of the bit line 123.

Referring to FIG. 2F, the interlayer insulating layer 124 and a portion of the insulating layer 128 which is formed on the outer sidewalls of the storage nodes 130 are removed so that the storage nodes 130 are protruded from an upper surface of the bit line 123. At this time, the removed portion of the insulating layer 128 corresponds to the thickness of the interlayer insulating layer 124. By removing the interlayer insulating layer 124 and the insulating layer 128 formed on the outer sidewalls of the storage nodes 130, the storage nodes 130 have a cylindrical shape at the upper portion and has a concave shape at the lower portion. That is, the upper portion of the storage nodes 130 have a cylindrical shape to ensure the capacitance and the lower portion of the storage nodes 130 have a concave shape to prevent the collapse of the storage nodes 130.

Referring to FIG. 2G, a dielectric layer 132 is formed on the storage node 130. At this time, the dielectric layer 132 may preferably have a stack structure of ZrO₂, Al₂O₃, and ZrO₂.

Referring to FIG. 2H, an upper electrode 137 is formed on an entire resultant structure. Herein, the upper electrode 137 preferably has a stack structure of a TiN layer 134 and a polysilicon layer 136.

As described above, according to an embodiment of the present invention, the bit line 123 is formed in the active region 104 so that the bit line 123 and the storage nodes 130 can be formed on a same cross-sectional plane. Under this configuration, the storage node 130 can be formed to directly contact the second conduction plug 116 without passing through additional contact plugs. Since the storage node contact is directly contacting the second conduction plug 116, processing time and cost can be significantly reduced. Furthermore, a processing margin for forming the bit line 124 and the storage nodes 130 can be better ensured.

FIGS. 3a through 3F are diagrams illustrating a method of manufacturing a semiconductor device according to another embodiment of the present invention, wherein (i) is a plan view and (ii) is a sectional view taken along the line x-x1 of (i). FIGS. 3G through 3M are sectional views illustrating a method of manufacturing the semiconductor device according to another embodiment of the inventive concept, wherein FIGS. 3G through 3M illustrate a method of forming a lower electrode including an additional storage node extended upward from the storage node 130 which is formed according to the embodiment of FIGS. 2A to 2H.

Accordingly, processes as shown in FIGS. 3A through 3F are the same as the processes shown in FIGS. 2A through 2F. The reference numeral of FIGS. 3A through 3F is changed to avoid confusion with reference numerals of FIGS. 2A through 2H. In FIGS. 2A through 2H, 200 designates a semiconductor substrate, 202 denotes an isolation layer, 204 denotes an active region, 206 denotes a gate polysilicon layer, 208 denotes a gate metal layer, 210 denotes a hard mask layer, 212 denotes a silicon nitride layer, 218 denotes an interlayer insulating layer, 220 denotes a bit line conduction layer, 222 denotes a hard mask layer, 223 denotes a bit line, 224 denotes an interlayer insulating layer, 226 denotes holes, 228 denotes an insulating layer and 230 denotes storage nodes.

Referring to FIG. 3G, an etching stop layer 232 and interlayer insulating layers 234 and 236 are formed on the entire resultant structure including lower storage nodes 230 protruded upward from the bit line 223. Herein, the etching stop layer 232 may preferably include a nitride layer, and the interlayer insulating layer 234 may preferably include a PSG(PhosphoSilicate Glass) layer, and the interlayer insulating layer 236 may preferably include TEOS(Tetra Ethyl Ortho Silicate Glass).

Referring to FIG. 3H, portions of the interlayer insulating layers 234 and 236 and the etching stop layer 232 are etched to expose the lower storage nodes 230, thereby forming holes 238. Herein, the etching stop layer 232 is formed over the lower storage nodes 230. This configuration provides accurate more reliable electrical connection between lower storage nodes 230 and upper storage nodes 240 which will be formed over the lower storage nodes 230 in a subsequent process.

Referring to FIG. 3I, a conductive layer for the upper storage nodes 240 is formed over the holes 238 and the interlayer insulating layer 236. Herein, the conductive layer for the upper storage nodes 240 may preferably include any one of Ti, TiN and a combination thereof.

Referring to FIG. 3J, the conductive layer for the upper storage nodes 240 are etched back to form the upper storage nodes 240 over an inner sidewall of the holes 238. At this time, a portion of the etching stop layer 232 may be removed, when the portion of the upper storage nodes 240 which is disposed on the etching stop layer 232 is removed. Herein, the etching stop layer 232 may be preferably removed so as to have a height higher than the height of the bit line 223.

Referring to 3K, the interlayer insulating layers 234 and 236 and the etching stop layer 232 are removed and the etching stop layer 232 which is formed over the lower storage nodes 230 is also removed to expose the upper storage nodes 240 extended from the lower storage nodes 230. At this time, the interlayer insulating layers 234 and 236 and the etching stop layer 232 may be preferably removed by a full dip-out process. HF can be used as an etchant for the full dip-out process. Herein, the upper storage nodes 240 has a cylinder shape and the lower storage nodes 230 has a cylinder shape protruded upward from the bit line 223 at the upper portion and has a concave shape at the lower portion. The extended storage node including the lower and the upper storage nodes 230 and 240 can provide enhanced capacitance. The extended storage node structure is especially useful when employed for a highly integrated semiconductor device which has a small contact area between the active region and the storage node.

Referring to FIG. 3L, a dielectric layer 242 is formed on the combined storage node including the lower and the upper storage nodes 230 and 240. At this time, the dielectric layer 242 may preferably include a stack structure of ZrO₂, Al₂O₃, and ZrO₂.

Referring to FIG. 3M, an upper electrode having a stack structure of a TiN layer 244 and a polysilicon layer 246 is formed over the dielectric layer 242.

As described above, according to another embodiment of the present invention, the bit line is formed on the active region and the storage node is formed to directly contact the conduction plug. Then an additional storage node is formed on the storage so that the storage node contact formation process can be omitted to reduce cost and the required processing time.

While certain embodiments have been described above, it will be understood that the embodiments described are by way of example only. Accordingly, the devices and methods described herein should not be limited based on the described embodiments. Rather, the systems and methods described herein should only be limited in light of the claims that follow when taken in conjunction with the above description and accompanying drawings.

What is claimed is:

1. A semiconductor device, comprising:
first, second and third conduction plugs disposed on an active region, the second conduction plug being provided between the first and third conduction plugs;
a bit line electrically coupled to the second conduction plug and passing over the active region; and
first and second storage nodes electrically coupled to the first and third conduction plugs, respectively.

2. The semiconductor device of claim 1, wherein the first and second storage nodes extend through the bit line.

3. The semiconductor device of claim 2, wherein a bottom of the first and second storage nodes have a slit shape elongated in a longitudinal direction of the bit line.

4. The semiconductor device of claim 2, further comprising an insulating layer disposed on lower portions of sidewalls of the first and second storage nodes.

5. The semiconductor device of claim 1, wherein the insulating layer is disposed on sidewalls of the bit line.

6. The semiconductor device of claim 4, wherein the insulating layer comprises an oxide layer or a nitride layer, the insulating layer having a thickness of 50 Å to 100 Å.

7. The semiconductor device of claim 1, wherein an upper portion of the first and second storage node has a cylindrical shape and a lower portion of each storage node has a concave shape.

8. The semiconductor device of claim 1, further comprising:
a dielectric layer disposed on a surface of the first and second storage nodes; and
an upper electrode disposed on a surface of the dielectric layer, wherein the dielectric layer comprises a stack structure of ZrO₂, Al₂O₃, and ZrO₂.

9. A semiconductor device, comprising:
an active region formed over a substrate ;
a gate pattern formed in the active region;
a first conduction plug formed at a first side of the gate pattern, and a second conduction plug formed at a second side of the gate pattern;
a bit line electrically coupled to the first conduction plug; and
a storage node coupled to the second conduction plug ,
wherein the storage node and the bit line are formed in the same cross-sectional plane as a cross-sectional plane of the active region.

10. A method for manufacturing a semiconductor device, comprises:
forming first, second and third conduction plugs on an active region, the second conduction plug being provided between the first and third conduction plugs;
forming a bit line electrically coupled to the second conduction plug and passing over the active region; and
forming first and second storage nodes electrically coupled to the first and third conduction plug, respectively,
wherein the bit line and the first and second storage nodes are formed in the same cross-sectional plane as a cross-sectional plane of the active region.

11. A method of manufacturing a semiconductor device, comprises:
forming first, second and third conduction plugs disposed on an active region, the second conduction plug being provided between the first and third conduction plugs;
forming a bit line electrically coupled to the second conduction and passing over the active region; and
forming first and second storage nodes electrically coupled to first and third conduction plugs, respectively, the first conduction plug contacting one end of the active region and third conduction plug contacting an opposing end of the active region.

12. The method of claim 11, before the forming the first, second and third conduction plugs, further comprises forming recess gates.

13. The method of claim 11, wherein the forming a bit line comprises:
forming a first interlayer insulating layer on the first, second and third of conduction plugs;
forming a first photosensitive pattern on the first interlayer insulating layer exposing the second conduction plug ;
etching the first interlayer insulating layer by using the first photosensitive pattern as an etch mask;
forming a bit line conduction layer to be buried within an etched portion of the interlayer insulating layer;
forming a second photosensitive pattern on the bit line conduction layer to cover the active region; and
etching the bit line conduction layer by using the second photosensitive pattern as an etch mask.

14. The method of claim 11, after the forming the bit line, further comprises forming bit line spacers on sidewalls of the bit line.

15. The method of claim 11, after the forming the bit line, further comprises forming a second interlayer insulating layer.

16. The method of claim 15, wherein the forming the first and second storage nodes comprises:
forming holes exposing the first and third conduction plugs disposed on the active region;
forming an insulating layer on sidewalls of the holes;
forming a storage node material on exposed the first and third conduction plugs and sidewalls of the insulating layer; and
removing the second interlayer insulating layer and the insulating layer to form lower storage nodes.

17. The method of claim 16, wherein the forming holes comprises etching the second interlayer insulating layer, the bit line and the first interlayer insulating layer.

18. The method of claim 16, wherein the forming the insulating layer on sidewalls of holes comprises:
forming an insulating material on the holes; and
etching back the insulating material.

19. The method of claim 16, wherein after forming the lower storage nodes, the method further comprises:
forming an etching stop layer and third and fourth interlayer insulating layers on the lower storage nodes;
forming upper holes by etching the third and fourth interlayer insulating layers to expose the etching stop layer;
forming a storage node material on the upper holes;
etching back the storage node material; and
forming upper storage nodes by removing the third and fourth interlayer insulating layers to expose the etching stop layer and by removing the etching stop layer to expose the first and third conduction plugs.

20. The method of claim 19, wherein the forming the second storage nodes comprises carrying out a full dip out process using HF.

21. The method of claim 16, further comprises:
forming a dielectric layer on a surface of the storage nodes; and
forming an upper electrode on the dielectric layer.
